(19) United States
(12) Patent Application Publication
(10) Pub. No.: US 2025/0089296 A1
(43) Pub. Date: Mar. 13, 2025

(54) SEMICONDUCTOR DEVICE INCLUDING TRANSISTOR

(71) Applicant: SK hynix Inc., Gyeonggi-do (KR)

(72) Inventor: Dong Jin KO, Gyeonggi-do (KR)

(21) Appl. No.: 18/595,430

(22) Filed: Mar. 5, 2024

(30) Foreign Application Priority Data
Sep. 7, 2023 (KR) 10-2023-0118970

(51) Int. Cl. H01L 29/786; H10B 12/00

(52) U.S. Cl. CPC H10D 30/6728; H10B 12/31; H10B 12/33; H10D 30/6733; H10D 30/6755

(57) ABSTRACT

A semiconductor device includes a substrate; a first electrode layer disposed over the substrate; an interlayer insulating layer having an opening that exposes the first electrode layer; an oxide semiconductor layer formed along a surface of the opening and connected to the first electrode layer; a gate insulating layer formed along a surface of the oxide semiconductor layer; a stacked structure including a first gate electrode layer, a first insulating layer, a second gate electrode layer, and a second insulating layer stacked in a vertical direction while filling a remaining space of the opening in which the oxide semiconductor layer and the gate insulating layer are formed; and a second electrode layer disposed over the stacked structure and the oxide semiconductor layer and connected to the oxide semiconductor layer.

### CROSS-REFERENCE TO RELATED APPLICATION

This application claims priority under 35 U.S.C. § 119 to Korean Patent Application No. 10-2023-0118970 filed on Sep. 7, 2023, which is incorporated herein by reference in its entirety.

### BACKGROUND

### 1. Technical Field

Embodiments of the present disclosure relate to a semiconductor technology, and particularly, to a semiconductor device including a transistor.

### 2. Related Art

With the development of the electronics industry, electronic products are becoming increasingly smaller, higher-performance, and more highly integrated, while the operating speed of the electronic products is required to increase.

To meet these demands, there is a need to develop technologies that can maintain and/or improve the characteristics of unit elements that make up electronic products, such as transistors, while reducing their size. In addition, technology using an oxide semiconductor as a channel of a transistor is also being developed.

### SUMMARY

In an embodiment of the present disclosure, a semiconductor device may include: a substrate; a first electrode layer disposed over the substrate; an interlayer insulating layer having an opening that exposes the first electrode layer; an oxide semiconductor layer formed along a surface of the opening and connected to the first electrode layer; a gate insulating layer formed along a surface of the oxide semiconductor layer; a stacked structure including a first gate electrode layer, a first insulating layer, a second gate electrode layer, and a second insulating layer stacked in a vertical direction while filling a remaining space of the opening in which the oxide semiconductor layer and the gate insulating layer are formed; and a second electrode layer disposed over the stacked structure and the oxide semiconductor layer and connected to the oxide semiconductor layer.

In another embodiment of the present disclosure, a semiconductor device may include: a substrate; a first electrode layer disposed over the substrate; a stacked structure disposed over the first electrode layer and including a first insulating layer, a first gate electrode layer, a second insulating layer, and a second gate electrode layer that are stacked in a vertical direction; a gate insulating layer formed along a sidewall of the first gate electrode layer and a sidewall and an upper surface of the second gate electrode layer; an oxide semiconductor layer formed along a surface of the stacked structure over which the gate insulating layer is formed and a surface of the first electrode layer; and a second electrode layer connected to the oxide semiconductor layer over the oxide semiconductor layer.

These and other features and advantages of the invention will become apparent from the detailed description of embodiments of the present disclosure and the following figures.

### BRIEF DESCRIPTION OF THE DRAWINGS

FIGS. 1A to 5B are views illustrating a semiconductor device according to an embodiment of the present disclosure, and a method for fabricating the same.

FIG. 6 is a time-voltage graph illustrating the operation of a semiconductor device according to an embodiment of the present disclosure.

FIG. 7 is a cross-sectional view illustrating a semiconductor device according to another embodiment of the present disclosure, and a method for fabricating the same.

FIGS. 8A to 11B are views illustrating a semiconductor device according to another embodiment of the present disclosure, and a method for fabricating the same.

FIG. 12 is a cross-sectional view illustrating a semiconductor device according to another embodiment of the present disclosure, and a method for fabricating the same.

### DETAILED DESCRIPTION

Hereinafter, various embodiments of the present disclosure will be described in detail with reference to the accompanying drawings.

The drawings are not necessarily drawn to scale. In some instances, proportions of at least some structures in the drawings may have been exaggerated to clearly illustrate certain features of the described embodiments. In presenting a specific example in a drawing or description having two or more layers in a multi-layer structure, the relative positioning relationship of such layers or the sequence of arranging the layers as shown reflects a particular implementation for the described or illustrated example and a different relative positioning relationship or sequence of arranging the layers may be possible. In addition, a described or illustrated example of a multi-layer structure might not reflect all layers present in that particular multilayer structure (e.g., one or more additional layers may be present between two illustrated layers). As a specific example, when a first layer in a described or illustrated multi-layer structure is referred to as being “on” or “over” a second layer or “on” or “over” a substrate, the first layer may be directly formed on the second layer or the substrate but may also represent a structure where one or more other intermediate layers may exist between the first layer and the second layer or the substrate.

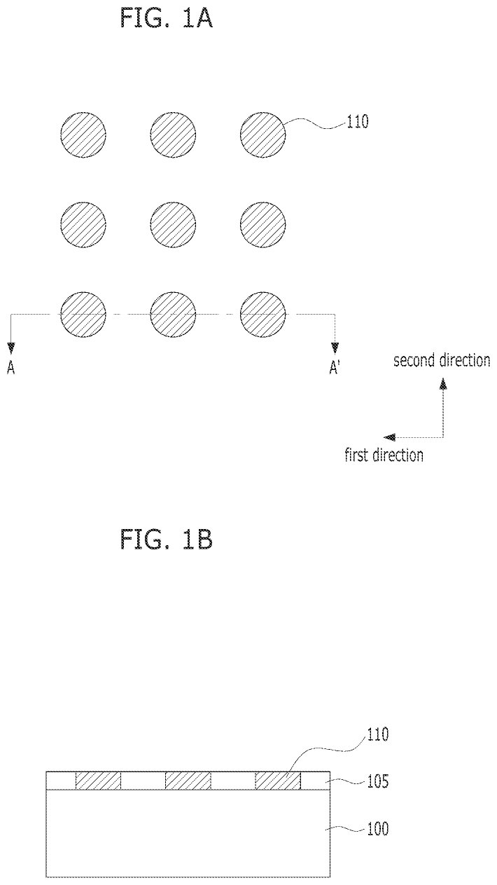

FIGS. 1A to 5B are views illustrating a semiconductor device according to an embodiment of the present disclosure, and a method for fabricating the same. FIGS. 1A, 2A, 3A, 4A, and 5A show plan views, and FIGS. 1B, 2B, 3B, 4B, and 5B show cross-sectional views taken along a line A-A′ of FIGS. 1A, 2A, 3A, 4A, and 5A, respectively.

Hereinafter, the fabricating method will first be described.

Referring to FIGS. 1A and 1B, a substrate 100 may be provided. The substrate 100 may include a semiconductor material such as silicon. Additionally, a required lower structure may be formed within the substrate 100.

Subsequently, a first electrode layer 110 and a first interlayer insulating layer 105 may be formed over the substrate 100.

The first electrode layer 110 may correspond to one of a source electrode and a drain electrode that are respectively connected to both ends of a transistor. For example, the first electrode layer 110 may correspond to a source electrode. The first electrode layer 110 may have an island shape in a plan view. In an embodiment, the first electrode layer 110 has a circular shape in a plan view, but the present disclosure is not limited thereto, and the planar shape of the first electrode layer 110 may be modified in various ways. In a plan view, a plurality of first electrode layers 110 may be arranged in a matrix form along a first direction parallel to the line A-A′ and a second direction intersecting the line A-A′. For reference, the first direction and the second direction may correspond to a horizontal direction substantially parallel to the upper surface of the substrate 100. A direction substantially perpendicular to the upper surface of the substrate 100 will hereinafter be referred to as a vertical direction. The first electrode layer 110 may include at least one of various conductive materials. For example, the first electrode layer 110 may include a metal such as platinum (Pt), tungsten (W), aluminum (Al), copper (Cu), tantalum (Ta), titanium (Ti), ruthenium (Ru), or molybdenum (Mo), as well as an oxide, nitride, or alloy containing at least one of these metals.

The first interlayer insulating layer 105 may be formed to fill the space between the plurality of first electrode layers 110. The first interlayer insulating layer 105 may include at least one of various insulating materials, such as silicon oxide, silicon nitride, silicon oxynitride, or a combination thereof.

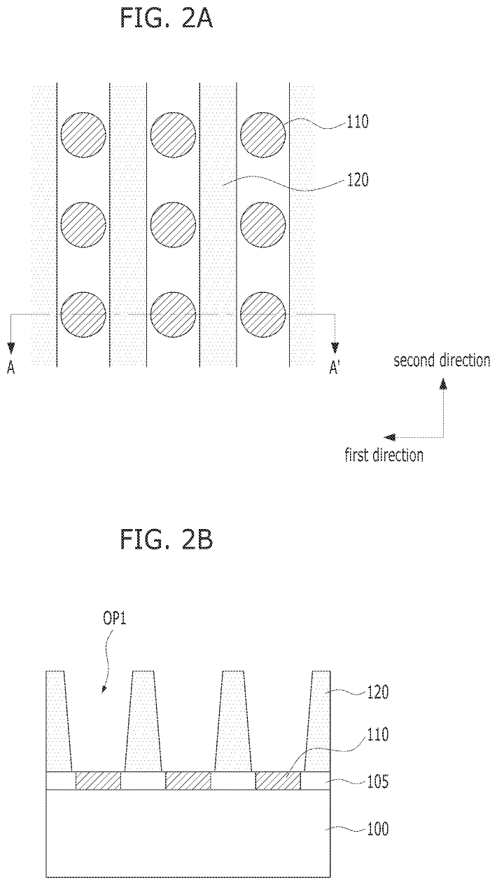

Referring to FIGS. 2A and 2B, a second interlayer insulating layer 120 may be formed over the first electrode layer 110 and the first interlayer insulating layer 105. The second interlayer insulating layer 120 may have a line-shaped opening OP1 that extends in the second direction and exposes the row of the first electrode layers 110 arranged in the second direction. The second interlayer insulating layer 120 may include at least one of various insulating materials, such as silicon oxide, silicon nitride, silicon oxynitride, or a combination thereof.

The second interlayer insulating layer 120 may be formed by depositing an insulating material over the first electrode layer 110 and the first interlayer insulating layer 105, and selectively etching the insulating material to expose the row of the first electrode layers 110 arranged in the second direction. The etching of the insulating material may be performed by anisotropic etching, such as dry etching. In the first direction, the second interlayer insulating layer 120 may have a width that increases from top to bottom. In the first direction, the width of the opening OP1 of the second interlayer insulating layer 120 may decrease from top to bottom. This may be because the upper portion of the second interlayer insulating layer 120 is exposed to the etching process for a longer time than the lower portion of the second interlayer insulating layer 120.

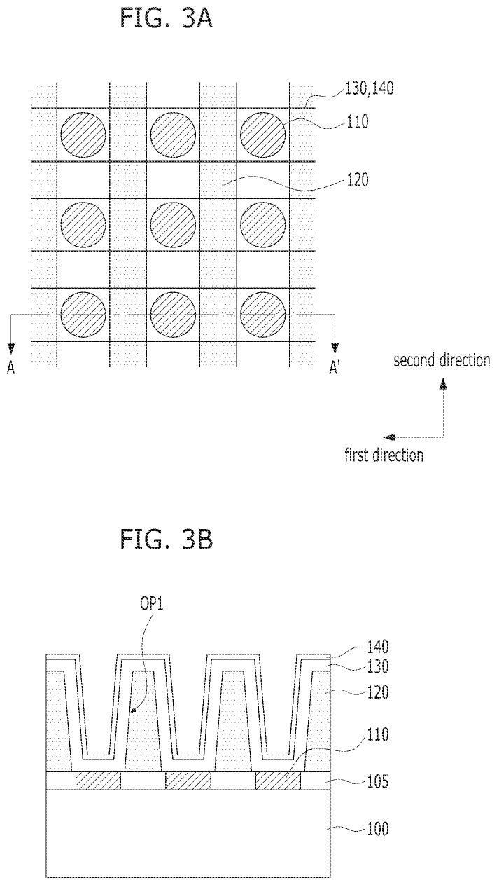

Referring to FIGS. 3A and 3B, an oxide semiconductor layer 130 and a gate insulating layer 140 may be formed over the process result of FIGS. 2A and 2B. The oxide semiconductor layer 130 and a gate insulating layer 140 may be formed by conformally depositing an oxide semiconductor material and a gate insulating material over the process result of FIGS. 2A and 2B and patterning the oxide semiconductor material and the gate insulating material in a line shape to overlap the row of the first electrode layers 110 arranged in the first direction. As a result, in a plan view, the oxide semiconductor layer 130 and the gate insulating layer 140 may have a line shape extending in the first direction, and a plurality of lines including the oxide semiconductor layers 130 and the gate insulating layer 140 may be separated from each other in the second direction. In an embodiment, the gate insulating layer 140 is patterned together with the oxide semiconductor layer 130, but the present disclosure is not limited thereto. In another embodiment, the gate insulating layer 140 may not be patterned. That is, the gate insulating layer 140 may be formed over the entire surface of the process result of FIGS. 2A and 2B.

The oxide semiconductor layer 130 may be a part that functions as a channel of a transistor and may include at least one of various oxide semiconductor materials such as indium gallium zinc oxide (IGZO), indium zinc tin oxide (IZTO), zinc tin oxide (ZTO), indium gallium oxide (IGO), or InO₂. The oxide semiconductor layer 130 may be deposited using various deposition methods such as ALD (Atomic Layer Deposition). The oxide semiconductor layer 130 may be formed conformally along the upper surface and the sidewall of the second interlayer insulating layer 120, the upper surface of the first electrode layer 110, and the upper surface of the first interlayer insulating layer 105. Accordingly, the lowermost surface of the oxide semiconductor layer 130, that is, the portion located at the lowest height in the vertical direction of the lower surface of the oxide semiconductor layer 130, may be in direct contact with the upper surface of the first electrode layer 110, and thus, the oxide semiconductor layer 130 may be electrically connected to the first electrode layer 110.

The gate insulating layer 140 may be a part that functions as a gate insulating layer of a transistor and may include at least one of various insulating materials such as silicon oxide, silicon nitride, silicon oxynitride, or a high dielectric constant material with a higher dielectric constant than silicon oxide. The gate insulating layer 140 may be deposited using at least one of various deposition methods such as ALD. The gate insulating layer 140 may be formed conformally along the upper surface of the oxide semiconductor layer 130.

The oxide semiconductor layer 130 and the gate insulating layer 140 may be formed to a thickness that does not completely fill the opening OP1 of the second interlayer insulating layer 120. Accordingly, a space may remain within the opening OP1.

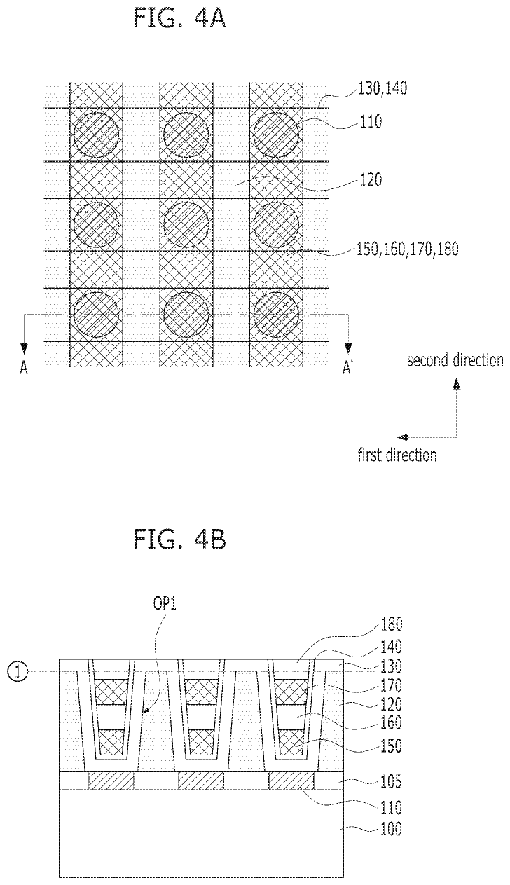

Referring to FIGS. 4A and 4B, a stacked structure 150, 160, 170, and 180 including a first gate electrode layer 150, a first insulating layer 160, a second gate electrode layer 170, and a second insulating layer 180 may be formed in the remaining space of the opening OP1. The sidewall and the lower surface of the stacked structure 150, 160, 170, and 180 may be surrounded by the gate insulating layer 140.

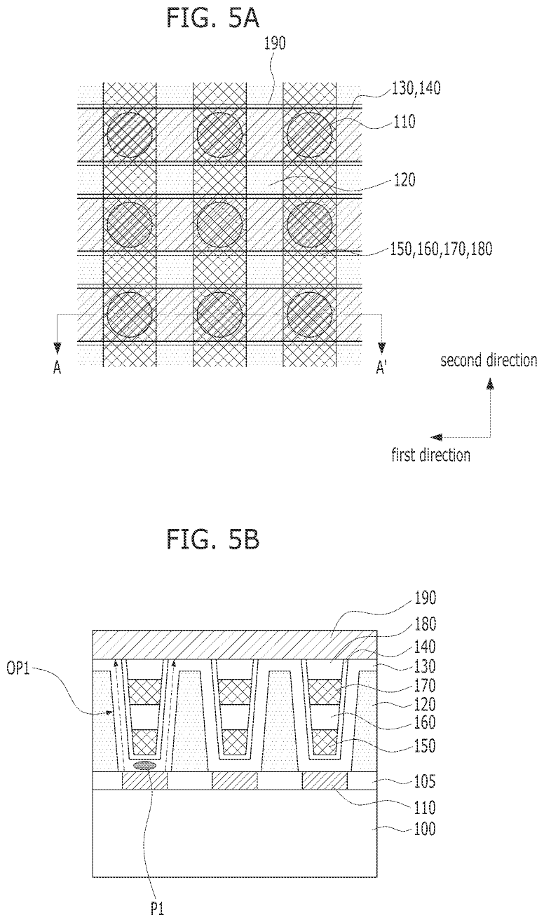

The first gate electrode layer 150 may be used to lower the Schottky barrier formed by contact between the first electrode layer 110 and the oxide semiconductor layer 130. On the other hand, the second gate electrode layer 170 may be used to control on/off of a transistor. This will be described in more detail when describing the operation of the semiconductor device described later. The first insulating layer 160 may be used to physically and electrically separate the first gate electrode layer 150 and the second gate electrode layer 170. The second insulating layer 180 may be used to physically and electrically separate the second gate electrode layer 170 and a second electrode layer (refer to 190 in FIGS. 5A and 5B), which will be described later. Each of the first gate electrode layer 150 and the second gate electrode layer 170 may include at least one of various conductive materials, for example, a metal such as platinum (Pt), tungsten (W), aluminum (Al), copper (Cu), tantalum (Ta), titanium (Ti), ruthenium (Ru), or molybdenum (Mo), as well as an oxide, nitride, or alloy containing at least one of these metals. The first gate electrode layer 150 and the second gate electrode layer 170 may be formed of the same material or may be formed of different materials. Each of the first insulating layer 160 and the second insulating layer 180 may include at least one of various insulating materials, such as silicon oxide, silicon nitride, silicon oxynitride, or a combination thereof. The first insulating layer 160 and the second insulating layer 180 may be formed of the same material or may be formed of different materials.

Since the stacked structure 150, 160, 170, and 180 is buried in the opening OP1, the stacked structure 150, 160, 170, and 180 may have a line shape extending in the second direction similar to the opening OP1, and accordingly, the stacked structure 150, 160, 170, and 180 may overlap the plurality of first electrode layers 110 arranged in the second direction. The stacked structure 150, 160, 170, and 180 may be formed in the following manner. First, a conductive material for forming the first gate electrode layer 150 may be deposited over the process result of FIGS. 3A and 3B to sufficiently fill the remaining space of the opening OP1, and then, the conductive material may be recessed using an etch-back method or the like until the desired thickness is reached to form the first gate electrode layer 150. Next, an insulating material for forming the first insulating layer 160 may be deposited over the process result in which the first gate electrode layer 150 is formed to sufficiently fill the remaining space of the opening OP1 in which the first gate electrode layer 150 is formed, and then, the insulating material may be recessed until the desired thickness is reached to form the first insulating layer 160. Next, a conductive material for forming the second gate electrode layer 170 may be deposited over the process result in which the first gate electrode layer 150 and the first insulating layer 160 are formed to sufficiently fill the remaining space of the opening OP1 in which the first gate electrode layer 150 and the first insulating layer 160 are formed, and then, the conductive material may be recessed until the desired thickness is reached to form the second gate electrode layer 170. Next, an insulating material for forming the second insulating layer 180 may be deposited over the process result in which the first gate electrode layer 150, the first insulating layer 160, and the second gate electrode layer 170 are formed to sufficiently fill the remaining space of the opening OP1 in which the first gate electrode layer 150, the first insulating layer 160, and the second gate electrode layer 170 are formed, and then, a planarization process such as CMP (Chemical Mechanical Polishing) may be performed so that the oxide semiconductor layer 130 is exposed to form the second insulating layer 180. As a result, the upper surface of the second insulating layer 180 may form a flat surface with the uppermost surface of the oxide semiconductor layer 130 while being located at substantially the same height as the uppermost surface of the oxide semiconductor layer 130. In this process, the gate insulating layer 140 located over the uppermost surface of the oxide semiconductor layer 130 may be removed.

In an embodiment, when forming the second insulating layer 180, the oxide semiconductor layer 130 is formed over the upper surface of the second interlayer insulating layer 120 by performing a planarization process until the upper surface of the oxide semiconductor layer 130 is exposed, but the present disclosure is not limited thereto. In another embodiment, when forming the second insulating layer 180, a planarization process may be performed to expose the second interlayer insulating layer 120. For example, a planarization process may be performed up to the line indicated by the dotted line \textcircled{1}. In this case, the uppermost surface of the oxide semiconductor layer 130 may be located at substantially the same height as the upper surface of the second insulating layer 180 and the upper surface of the second interlayer insulating layer 120 to form a flat surface. As long as the uppermost surface of the oxide semiconductor layer 130 is in contact with and electrically connected to the second electrode layer (refer to 190 in FIGS. 5A and 5B) to be described later, the height of the uppermost surface of the oxide semiconductor layer 130 may be modified in various ways.

Referring to FIGS. 5A and 5B, the second electrode layer 190 may be formed over the process result of FIGS. 4A and 4B.

The second electrode layer 190 may correspond to one of a source electrode and a drain electrode respectively connected to both ends of a transistor. For example, second electrode layer 190 may correspond to a drain electrode. In a plan view, the second electrode layer 190 may have a line shape extending in the first direction and may overlap the plurality of first electrode layers 110 arranged in the first direction. A plurality of second electrode layers 190 may be arranged spaced apart from each other in the second direction. The second electrode layer 190 may include at least one of various conductive materials. For example, the second electrode layer 190 may include a metal such as platinum (Pt), tungsten (W), aluminum (Al), copper (Cu), tantalum (Ta), titanium (Ti), ruthenium (Ru), or molybdenum (Mo), as well as an oxide, nitride, or alloy containing at least one of these metals.

The second electrode layer 190 may be electrically connected to the oxide semiconductor layer 130 by directly contacting the uppermost surface of the oxide semiconductor layer 130.

As a result, a semiconductor device including a transistor may be fabricated, as shown in FIGS. 5A and 5B.

Referring again to FIGS. 5A and 5B, the semiconductor device may include the substrate 100, the first electrode layer 110 disposed over the substrate 100, the second interlayer insulating layer 120 disposed over the first electrode layer 110 and having the opening OP1 exposing the first electrode layer 110, the oxide semiconductor layer 130 formed along the surface of the opening OP1 and electrically connected to the first electrode layer 110, the gate insulating layer 140 formed along the surface of the oxide semiconductor layer 130, the stacked structure 150, 160, 170, and 180 filling the remaining space of the opening OP1 where the gate insulating layer 140 and the oxide semiconductor layer 130 are formed and including the first gate electrode layer 150, the first insulating layer 160, the second gate electrode layer 170, and the second insulating layer 180 that are stacked from bottom to top, and the second electrode layer 190 disposed over the oxide semiconductor layer 130 and the stacked structure 150, 160, 170, and 180 and electrically connected to the oxide semiconductor layer 130.

The first electrode layer 110 may have an island shape, and the plurality of first electrode layers 110 may be arranged along the first and second directions. The second electrode layer 190 may have a line shape extending in the first direction to overlap the plurality of first electrode layers 110 arranged in the first direction. The plurality of second electrode layers 190 may be arranged spaced apart from each other in the second direction. The first electrode layer 110 and the second electrode layer 190 may correspond to a source electrode and a drain electrode of a transistor, respectively.

The stacked structure 150, 160, 170, and 180 may have a line shape extending in the second direction to overlap the plurality of first electrode layers 110 arranged in the second direction. The second gate electrode layer 170 may function to control on/off of a transistor. That is, when a voltage equal to or higher than a threshold voltage of a transistor is applied to the second gate electrode layer 170, the current flow (refer to a dotted arrow in FIG. 5B) may occur through the oxide semiconductor layer 130 between the first electrode layer 110 and the second electrode layer 190, that is, through the oxide semiconductor layer 130 formed along the sidewall of the stacked structure 150, 160, 170, and 180, thereby turning on the transistor. On the other hand, when a voltage applied to the second gate electrode layer 170 is lowered below the threshold voltage or removed, the current flow through the oxide semiconductor layer 130 may be extinguished and the transistor may be turned off. Therefore, the oxide semiconductor layer 130 between the first electrode layer 110 and the second electrode layer 190 may function as a channel for a transistor. The first gate electrode layer 150 may function to lower the Schottky barrier formed by contact between the oxide semiconductor layer 130 and the first electrode layer 110. When a predetermined voltage is applied to the first gate electrode layer 150 and conductive carriers accumulate in an area of the oxide semiconductor layer 130, which is adjacent to the first gate electrode layer 150, the Schottky barrier between the oxide semiconductor layer 130 and the first electrode layer 110 may be reduced, thereby reducing the contact resistance between the oxide semiconductor layer 130 and the first electrode layer 110. As a result, operating characteristics of a transistor may be improved. If the conductive carriers are electrons, the predetermined voltage may be a positive voltage. The accumulation area of the conductive carriers is indicated by reference numeral P1 in FIG. 5B. The voltage applied to the first gate electrode layer 150 and the voltage applied to the second gate electrode layer 170 may be independent of each other.

Since the components of the semiconductor device have been described in detail in the fabricating method, the detailed description thereof will be omitted here.

According to the semiconductor device and the fabricating method thereof, the following effects may be obtained.

First, since an oxide semiconductor is used as a channel of a transistor, various advantages resulting from it may be secured, such as reduction of off-state current.

In addition, because the oxide semiconductor channel extends in the vertical direction, problems due to the short channel effect, the floating body effect, or the like, may not occur.

In addition, by using an additional gate electrode in addition to a gate electrode that controls on/off of a transistor, the Schottky barrier that inevitably occurs between the source electrode and the oxide semiconductor channel may be lowered. That is, ohmic contact between the source electrode and the oxide semiconductor channel may be formed. Accordingly, operating characteristics of a transistor may be improved.

In addition, since the oxide semiconductor channel is simply formed by a deposition method such as ALD and there is no etching process, attack on the oxide semiconductor channel may be reduced, thereby reducing the deterioration of the characteristics of the oxide semiconductor channel.

Furthermore, since a gate insulating layer covering the oxide semiconductor channel is formed after forming the oxide semiconductor channel, the phenomenon of oxygen escaping from the oxide semiconductor channel and increasing oxygen vacancies in the oxide semiconductor channel, and the resulting problems may be solved.

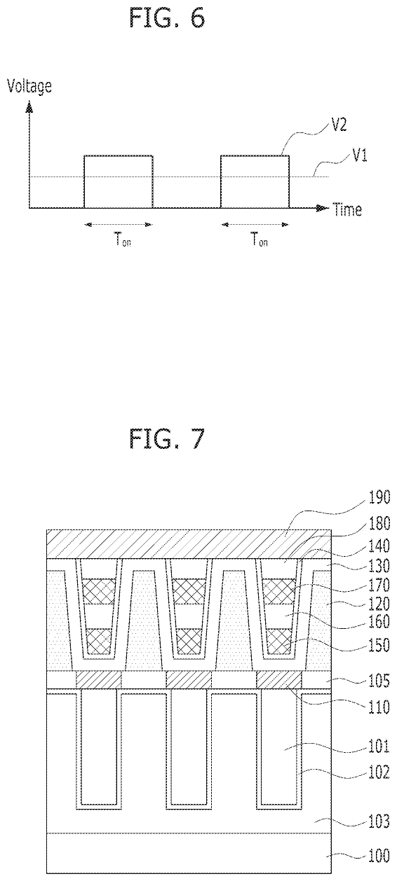

FIG. 6 is a time-voltage graph illustrating the operation of a semiconductor device according to an embodiment of the present disclosure.

Referring to FIG. 6 together with FIGS. 5A and 5B, a voltage applied to the first gate electrode layer 150 is denoted as a first voltage V1, and a voltage applied to the second gate electrode layer 170 is denoted as a second voltage V2.

The second voltage V2 may be applied only in the turn-on period Ton of the transistor and may not be applied in the remaining periods. The second voltage V2 may have a magnitude greater than the threshold voltage of the transistor.

On the other hand, since the first voltage V1 is for forming the ohmic contact between the oxide semiconductor layer 130 and the first electrode layer 110, the first voltage V1 may be applied not only in the turn-on period Ton of the transistor but also in the remaining periods, such as the turn-off period of the transistor. That is, the first voltage V1 may always be applied regardless of the operation of the transistor.

In an embodiment, the magnitude of the first voltage V1 is shown to be smaller than the magnitude of the second voltage V2, but the present disclosure is not limited thereto. The magnitude of the first voltage V1 and the magnitude of the second voltage V2 may be adjusted independently of each other. Accordingly, in another embodiment, the magnitude of the first voltage V1 and the magnitude of the second voltage V2 may be the same as each other, or the magnitude of the second voltage V2 may be smaller than the magnitude of the first voltage V1.

The semiconductor device of FIGS. 5A and 5B may further include a memory element connected to one end of a transistor. For example, the memory element may be connected to a source electrode. The memory element may store different data depending on the voltage or current applied through the transistor. In an embodiment, for example, the memory element may include a capacitor including two electrodes and dielectric material disposed between the two electrodes. Alternatively, as another example, the memory element may include a variable resistance layer that stores different data by switching between different resistance states. The variable resistance layer may include at least one of various materials used in resistive random-access memory (RRAM), phase-change random-access memory (PRAM), ferroelectric random-access memory (FRAM), magnetoresistive random-access memory (MRAM), or the like, for example, a metal oxide such as a transition metal oxide or a perovskite-based material, a phase change material such as a chalcogenide-based material, a ferroelectric material, or a ferromagnetic material, and may have a single-layer structure or a multi-layer structure. Since the first electrode layer 110 corresponding to the source electrode in the semiconductor device of FIGS. 5A and 5B is located at the bottom of the components of the transistor, the memory element may be disposed below the first electrode layer 110. This will be described with reference to FIG. 7.

FIG. 7 is a cross-sectional view illustrating a semiconductor device according to another embodiment of the present disclosure, and a method for fabricating the same. The description will focus on differences from the semiconductor device of FIGS. 5A and 5B.

Referring to FIG. 7, the semiconductor device may include a capacitor 101, 102, and 103 including a first capacitor electrode layer 101, a second capacitor electrode layer 103, and a capacitor insulating layer 102, in addition to the components of the semiconductor device of FIGS. 5A and 5B.

The capacitor 101, 102, and 103 may be positioned between the substrate 100 and the first electrode layer 110 in the vertical direction. The first capacitor electrode layer 101 may have a pillar shape that overlaps each of the plurality of first electrode layers 110, and may contact the lower surface of the first electrode layer 110 to be electrically connected to the first electrode layer 110. The second capacitor electrode layer 103 may have a shape surrounding the sidewalls and the lower surfaces of the plurality of first capacitor electrode layers 101. The capacitor insulating layer 102 may be interposed between the first capacitor electrode layer 101 and the second capacitor electrode layer 103. In an embodiment, for example, the capacitor insulating layer 102 may be formed conformally along the sidewall and lower surface of the first capacitor electrode layer 101.

The capacitor 101, 102, and 103 may be formed by the following method. First, a conductive material for forming the second capacitor electrode layer 103 may be deposited over the substrate 100, and the conductive material may be selectively etched to form the second capacitor electrode layer 130 that provides a space in which the capacitor insulating layer 102 and the first capacitor electrode layer 101 are to be buried. Subsequently, the capacitor insulating layer 102 may be conformally formed along the lower profile over the second capacitor electrode layer 103, and then, the remainder of the space where the capacitor insulating layer 102 is formed may be filled with a conductive material to form the first capacitor electrode layer 101. Subsequent processes after forming the capacitor 101, 102, and 103 may be substantially the same as the processes described in FIGS. 1A to 5B.

In general, a capacitor may be formed using a high temperature process. Therefore, if the capacitor is formed after forming an oxide semiconductor channel, the oxide semiconductor channel may be exposed to this high temperature process and its characteristics may be deteriorated. However, in this case, since the capacitors 101, 102, and 103 are formed before the formation of the oxide semiconductor layer 130, exposure of the oxide semiconductor layer 130 to high temperature processes may be prevented and/or reduced. As a result, it may be advantageous to maintain the characteristics of the oxide semiconductor layer 130.

In this case forming the capacitors 101, 102, and 103 of the shape as shown has been described, but the present disclosure is not limited thereto. As long as a capacitor is formed under the first electrode layer 110 and one of two electrodes of the capacitor is connected to the first electrode layer 110, the shape of the capacitor may be modified in various ways. Alternatively, another memory element, such as a variable resistance layer, may be formed under the first electrode layer 110 instead of the capacitor 101, 102, and 103. One end of the variable resistance layer may be electrically connected to the first electrode layer 110, and the other end of the variable resistance layer may be electrically connected to another conductive line.

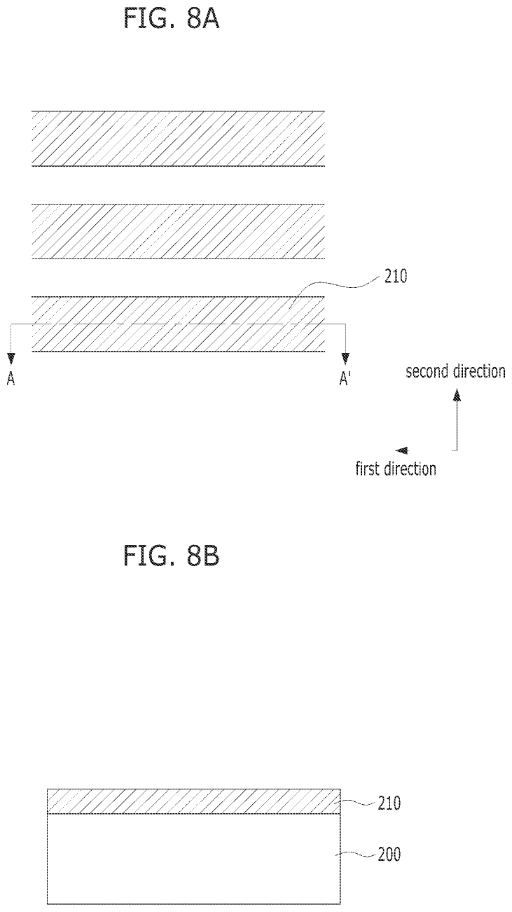

FIGS. 8A to 11B are views illustrating a semiconductor device according to another embodiment of the present disclosure, and a method for fabricating the same. FIGS. 8A, 9A, 10A, and 11A are plan views, and FIGS. 8B, 9B, 10B, and 11B are cross-sectional views taken along a line A-A′ of FIGS. 8A, 9A, 10A, and 11A, respectively.

Hereinafter, the fabricating method will first be described.

Referring to FIGS. 8A and 8B, a first electrode layer 210 may be formed over a substrate 200.

The first electrode layer 210 may correspond to one of a source electrode and a drain electrode respectively connected to both ends of a transistor. For example, the first electrode layer 210 may correspond to a drain electrode. In a plan view, the first electrode layer 210 may have a line shape extending in the first direction, and a plurality of first electrode layers 210 may be arranged spaced apart from each other in the second direction. The space between the plurality of first electrode layers 210 may be filled with a first interlayer insulating layer.

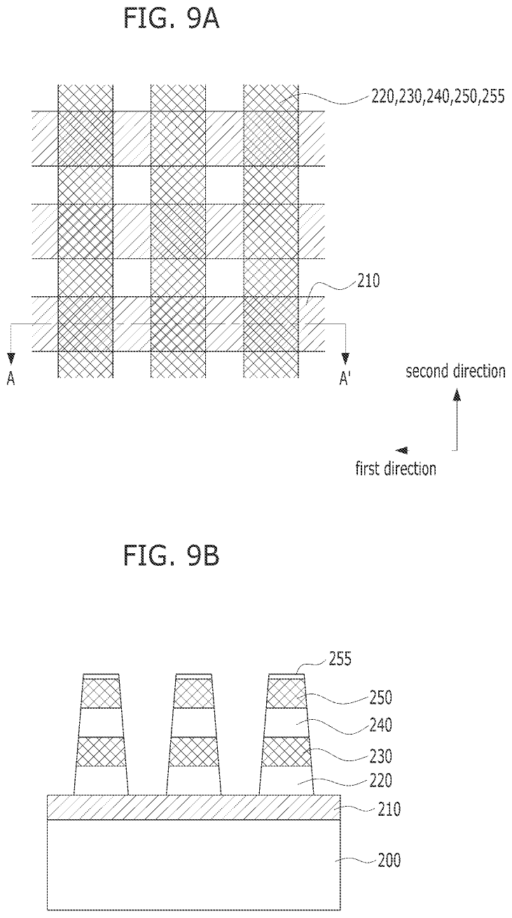

Referring to FIGS. 9A and 9B, a stacked structure 220, 230, 240, 250, and 255 including a first insulating layer 220, a first gate electrode layer 230, a second insulating layer 240, a second gate electrode layer 250, and a first gate insulating layer 255 may be formed over the first electrode layer 210 and the first interlayer insulating layer.

The first gate electrode layer 230 may function to control on/off of a transistor. The second gate electrode layer 250 may function to lower the Schottky barrier between a second electrode layer and an oxide semiconductor layer, which will be described later. The first insulating layer 220 may function to physically and electrically separate the first gate electrode layer 230 and the first electrode layer 210 from each other. The second insulating layer 240 may function to physically and electrically separate the first gate electrode layer 230 and the second gate electrode layer 250 from each other. The first gate insulating layer 255 may function as a gate insulating layer together with a second gate insulating layer, which will be described later.

The stacked structure 220, 230, 240, 250, and 255 may have a line shape extending in the second direction. A plurality of stacked structures 220, 230, 240, 250, and 255 may be formed spaced apart from each other in the first direction. The stacked structure 220, 230, 240, 250, and 255 may be formed by sequentially depositing an insulating material for forming the first insulating layer 220, a conductive material for forming the first gate electrode layer 230, an insulating material for forming the second insulating layer 240, a conductive material for forming the second gate electrode layer 250, and an insulating material for forming the first gate insulating layer 255, over the first electrode layer 210 and the first interlayer insulating layer, and selectively etching them. In the first direction, the stacked structure 220, 230, 240, 250, and 255 may have a width that increases from top to bottom. This may be because the upper portion of the stacked structure 220, 230, 240, 250, and 255 is exposed to the etching process for a longer time than the lower portion of the stacked structure 220, 230, 240, 250, and 255.

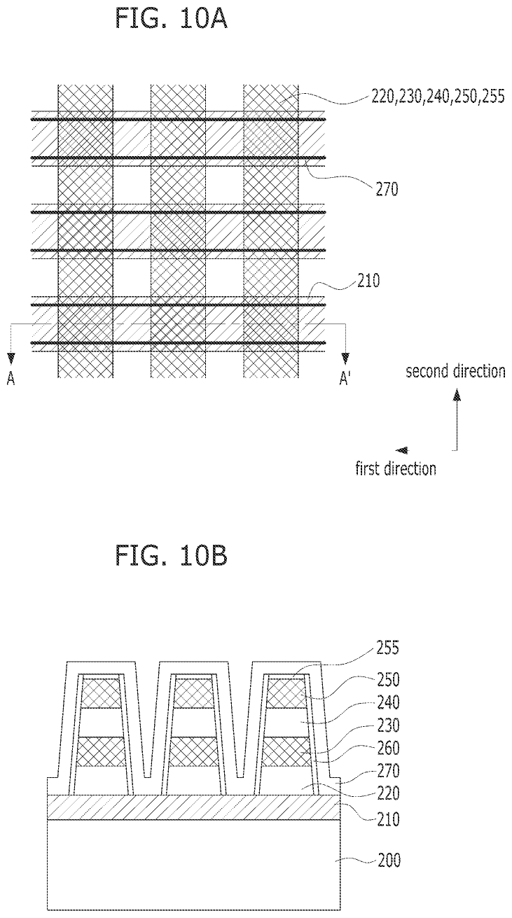

Referring to FIGS. 10A and 10B, a second gate insulating layer 260 may be formed over the sidewall of the stacked structure 220, 230, 240, 250, and 255.

The second gate insulating layer 260 may be formed by depositing a gate insulating material over the entire surface of the process result of FIGS. 9A and 9B using a method such as physical vapor deposition (PVD) or ALD and performing a blanket etching process. During the blanket etching process, the gate insulating material over the first gate insulating layer 255 and over the first electrode layer 210 may be removed to form the second gate insulating layer 260 located over the sidewall of the stacked structure 220, 230, 240, 250, and 255.

Subsequently, the oxide semiconductor layer 270 may be formed conformally along the lower profile over the process result in which the second gate insulating layer 260 is formed and may be patterned in a line shape to overlap the first electrode layer 210. As a result, in a plan view, the oxide semiconductor layer 270 may have a line shape extending in the first direction, and a plurality of oxide semiconductor layers 270 may be separated from each other in the second direction. The first gate electrode layer 230 and the oxide semiconductor layer 270 may be separated from each other by the second gate insulating layer 260. The second gate electrode layer 250 and the oxide semiconductor layer 270 may be separated from each other by the first gate insulating layer 255 and the second gate insulating layer 260. The lowermost surface of the oxide semiconductor layer 270 may contact the first electrode layer 210 and may be electrically connected to the first electrode layer 210. The oxide semiconductor layer 270 may be formed to a thickness that does not completely fill the space between the stacked structures 220, 230, 240, 250, and 255.

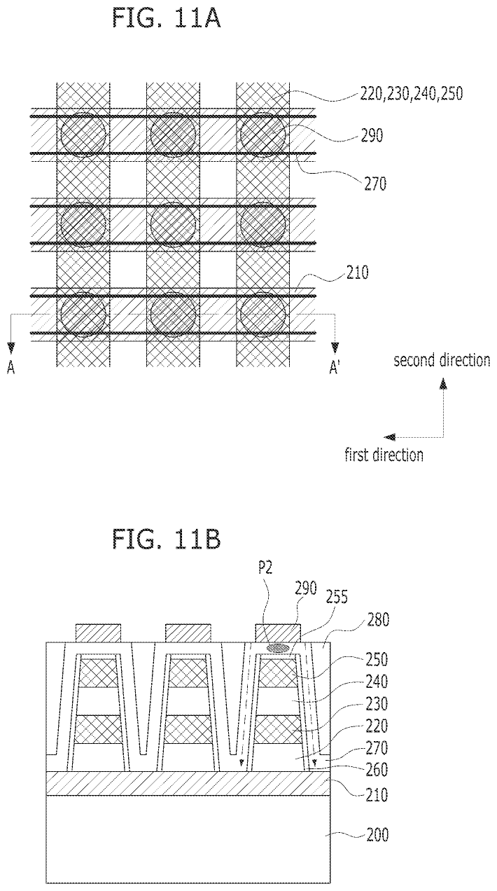

Referring to FIGS. 11A and 11B, a second interlayer insulating layer 280 may be formed to fill the remaining space between the stacked structures 220, 230, 240, 250, and 255.

The second interlayer insulating layer 280 may be formed by depositing an insulating material over the process result of FIGS. 10A and 10B to sufficiently fill the remaining space between the stacked structures 220, 230, 240, 250, and 255, and performing a planarization process to expose the oxide semiconductor layer 270. Accordingly, the uppermost surface of the oxide semiconductor layer 270 and the upper surface of the second interlayer insulating layer 280 may be located at substantially the same height and form a flat surface.

Subsequently, a second electrode layer 290 may be formed over the oxide semiconductor layer 270. The second electrode layer 290 may have an island shape and may have a lower surface in contact with the oxide semiconductor layer 270 to be electrically connected to the oxide semiconductor layer 270. The second electrode layer 290 may correspond to one of a source electrode and a drain electrode respectively connected to both ends of a transistor. For example, the second electrode layer 290 may correspond to a source electrode. In a plan view, a plurality of second electrode layers 290 may be arranged in a matrix form along the first and second directions. The plurality of second electrode layers 290 arranged in the first direction may overlap the first electrode layer 210 extending in the first direction, and the plurality of second electrode layers 290 arranged in the second direction may overlap the stacked structure 220, 230, 240, 250, and 255 extending in the second direction.

As a result, a semiconductor device including a transistor may be fabricated, as shown in FIGS. 11A and 11B.

Referring again to FIGS. 11A and 11B, the semiconductor device may include the substrate 200, the first electrode layer 210 disposed over the substrate 200, the stacked structure 220, 230, 240, 250, and 255 disposed over the first electrode layer 210 and including the first insulating layer 220, the first gate electrode layer 230, the second insulating layer 240, the second gate electrode layer 250, and the first gate insulating layer 255 that are stacked from bottom to top, the second gate insulating layer 260 formed along the sidewall of the stacked structure 220, 230, 240, 250, and 255, the oxide semiconductor layer 270 formed along the surface of the stacked structure 220, 230, 240, 250, and 255 on which the gate insulating layer 260 is formed and the surface of the first electrode layer 210 to be connected to the first electrode layer 210, and the second electrode layer 290 formed over the oxide semiconductor layer 270 to be connected to the oxide semiconductor layer 270.

The second electrode layer 290 may have an island shape, and a plurality of second electrode layers 290 may be arranged along the first and second directions. On the other hand, the first electrode layer 210 may have a line shape extending in the first direction to overlap the plurality of second electrode layers 290 arranged in the first direction. The plurality of first electrode layers 210 may be arranged spaced apart from each other in the second direction. The first electrode layer 210 and the second electrode layer 290 may correspond to a drain electrode and a source electrode of a transistor, respectively.

The stacked structure 220, 230, 240, 250, and 255 may have a line shape extending in the second direction to overlap the plurality of second electrode layers 290 arranged in the second direction. The first gate electrode layer 230 may function to control on/off of a transistor. That is, when a voltage equal to or higher than a threshold voltage of a transistor is applied to the first gate electrode layer 230, the current flow (refer to a dotted arrow in FIG. 11B) may occur through the oxide semiconductor layer 270 between the first electrode layer 210 and the second electrode layer 290, thereby turning on the transistor. On the other hand, when a voltage applied to the first gate electrode layer 230 is lowered below the threshold voltage or removed, the current flow through the oxide semiconductor layer 270 may be extinguished and the transistor may be turned off. The second gate electrode layer 250 may function to lower the Schottky barrier formed by contact between the oxide semiconductor layer 270 and the second electrode layer 290. When a predetermined voltage, such as a positive voltage, is applied to the second gate electrode layer 250 and conductive carriers, such as electrons, accumulate in an area adjacent to the second gate electrode layer 250 of the oxide semiconductor layer 270, the Schottky barrier between the oxide semiconductor layer 270 and the second electrode layer 290 may be reduced, thereby reducing the contact resistance between the oxide semiconductor layer 270 and the second electrode layer 290. As a result, operating characteristics of a transistor may be improved. The accumulation area of the conductive carriers is indicated by reference numeral P2 in FIG. 11B.

Since the components of the semiconductor device have been described in detail in the fabricating method, the detailed description thereof will be omitted here.

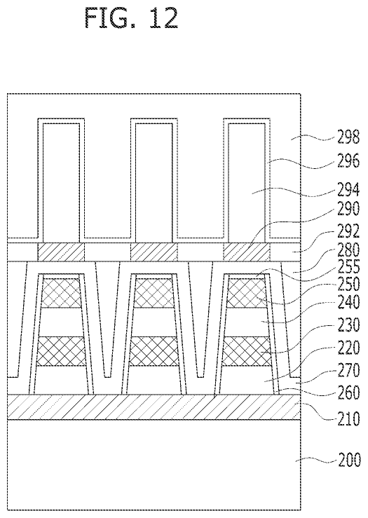

The semiconductor device of FIGS. 11A and 11B may further include a memory element connected to one end of a transistor. For example, the memory element may be connected to a source electrode. The memory elements may include a capacitor, a variable resistance layer, or the like. Since the second electrode layer 290 corresponding to the source electrode in the semiconductor device of FIGS. 11A and 11B is located at the top of the components of the transistor, the memory element may be disposed over the second electrode layer 290. This will be described with reference to FIG. 12.

FIG. 12 is a cross-sectional view illustrating a semiconductor device according to another embodiment of the present disclosure, and a method for fabricating the same. The description will focus on differences from the semiconductor device of FIGS. 11A and 11B.

Referring to FIG. 12, the semiconductor device may include a third interlayer insulating layer 292 that fills the space between the second electrode layers 290, and a capacitor 294, 296, and 298 including a first capacitor electrode layer 294, a second capacitor electrode layer 298, and a capacitor insulating layer 296, in addition to the components of the semiconductor device of FIGS. 11A and 11B.

The capacitor 294, 296, and 298 may be positioned over the second electrode layer 290 in the vertical direction. In an embodiment, the first capacitor electrode layer 294 may have a pillar shape that overlaps each of the plurality of second electrode layers 290, and may contact the upper surface of the second electrode layer 290 to be electrically connected to the second electrode layer 290. The second capacitor electrode layer 298 may have a shape surrounding the sidewalls and the upper surfaces of the plurality of first capacitor electrode layers 294. The capacitor insulating layer 296 may be interposed between the first capacitor electrode layer 294 and the second capacitor electrode layer 298. In an embodiment, for example, the capacitor insulating layer 296 may be formed conformally along the sidewall and the upper surface of the first capacitor electrode layer 294.

The capacitor 294, 296, and 298 may be formed by the following method. First, a conductive material for forming the first capacitor electrode layer 294 may be deposited over the second electrode layer 290 and the third interlayer insulating layer 292, and the conductive material may be selectively etched to form a pillar-shaped first capacitor electrode layer 294. Then, the capacitor insulating layer 296 may be conformally formed along the entire surface of the process result, and a conductive material may be deposited over the capacitor insulating layer 296 to a thickness that sufficiently covers the first capacitor electrode layer 294 to form the second capacitor electrode layer 298.

The case of forming the capacitor 294, 296, and 298 as shown has been described, but the present disclosure is not limited thereto. As long as a capacitor is formed over the second electrode layer 290 and one of two electrodes of the capacitor is connected to the second electrode layer 290, the shape of the capacitor may be modified in various ways. Alternatively, another memory element, such as a variable resistance layer, may be formed over the second electrode layer 290 instead of the capacitor 294, 296, and 298. One end of the variable resistance layer may be electrically connected to the second electrode layer 290, and the other end of the variable resistance layer may be electrically connected to another conductive line.

According to the above embodiments of the present disclosure, it may be possible to provide a semiconductor device that improves its operating characteristics while facilitating the manufacturing process.

Although various embodiments have been described for illustrative purposes, it will be apparent to those skilled in the art that various changes and modifications may be made without departing from the scope of the present disclosure. Furthermore, the embodiments may be combined to form additional embodiments.

What is claimed is:

1. A semiconductor device comprising:
a substrate;
a first electrode layer disposed over the substrate;
an interlayer insulating layer having an opening that exposes the first electrode layer;
an oxide semiconductor layer formed along a surface of the opening and connected to the first electrode layer;
a gate insulating layer formed along a surface of the oxide semiconductor layer;
a stacked structure including a first gate electrode layer, a first insulating layer, a second gate electrode layer, and a second insulating layer stacked in a vertical direction while filling a remaining space of the opening in which the oxide semiconductor layer and the gate insulating layer are formed; and
a second electrode layer disposed over the stacked structure and the oxide semiconductor layer and connected to the oxide semiconductor layer.

2. The semiconductor device according to claim 1, wherein the first electrode layer and the oxide semiconductor layer are in direct contact with each other to form a Schottky barrier, and
wherein the first gate electrode layer functions to reduce the Schottky barrier.

3. The semiconductor device according to claim 2, wherein, according to a first voltage applied to the first gate electrode layer, conductive carriers are accumulated in an area of the oxide semiconductor layer, which is adjacent to the first gate electrode layer.

4. The semiconductor device according to claim 3, wherein the first voltage is applied to the first gate electrode layer during a turn-on period and a turn-off period of a transistor.

5. The semiconductor device according to claim 1, wherein, according to a second voltage applied to the second gate electrode layer, a current flow is generated through the oxide semiconductor layer between the first electrode layer and the second electrode layer.

6. The semiconductor device according to claim 5, wherein the second voltage is applied to the second gate electrode layer in a turn-on period of a transistor.

7. The semiconductor device according to claim 1, wherein the first electrode layer has an island shape,
wherein a plurality of first electrode layers are arranged along a first direction parallel to an upper surface of the substrate and a second direction, the second direction being parallel to the upper surface of the substrate and intersecting the first direction,
wherein the stacked structure extends in the second direction to overlap the plurality of first electrode layers arranged in the second direction, and
wherein the second electrode layer extends in the first direction to overlap the plurality of first electrode layers arranged in the first direction.

8. The semiconductor device according to claim 1, wherein the stacked structure has a width that decreases from top to bottom.

9. The semiconductor device according to claim 1, further comprising:
a memory element electrically connected to the first electrode layer between the first electrode layer and the substrate.

10. A semiconductor device comprising:
a substrate;
a first electrode layer disposed over the substrate;
a stacked structure disposed over the first electrode layer and including a first insulating layer, a first gate electrode layer, a second insulating layer, and a second gate electrode layer that are stacked in a vertical direction;
a gate insulating layer formed along a sidewall of the first gate electrode layer and a sidewall and an upper surface of the second gate electrode layer;
an oxide semiconductor layer formed along a surface of the stacked structure over which the gate insulating layer is formed and a surface of the first electrode layer; and
a second electrode layer connected to the oxide semiconductor layer over the oxide semiconductor layer.

11. The semiconductor device according to claim 10, wherein the first electrode layer and the oxide semiconductor layer are in direct contact with each other to form a Schottky barrier, and
wherein the second gate electrode layer functions to reduce the Schottky barrier.

12. The semiconductor device according to claim 11, wherein, according to a second voltage applied to the second gate electrode layer, conductive carriers are accumulated in an area of the oxide semiconductor layer, which is adjacent to the second gate electrode layer.

13. The semiconductor device according to claim 12, wherein the second voltage is applied to the second gate electrode layer during a turn-on period and a turn-off period of a transistor.

14. The semiconductor device according to claim 10, wherein, according to a first voltage applied to the first gate electrode layer, a current flow is generated through the oxide semiconductor layer between the first electrode layer and the second electrode layer.

15. The semiconductor device according to claim 14, wherein the first voltage is applied to the first gate electrode layer in a turn-on period of a transistor.

16. The semiconductor device according to claim 1, wherein the second electrode layer has an island shape,
wherein a plurality of second electrode layers are arranged along a first direction parallel to an upper surface of the substrate and a second direction, the second direction being parallel to the upper surface of the substrate and intersecting the first direction,
wherein the stacked structure extends in the second direction to overlap the plurality of second electrode layers arranged in the second direction, and
wherein the first electrode layer extends in the first direction to overlap the plurality of second electrode layers arranged in the first direction.

17. The semiconductor device according to claim 10, wherein the stacked structure has a width that increases from top to bottom.

18. The semiconductor device according to claim 10, further comprising:
a memory element electrically connected to the second electrode layer over the second electrode layer.
